(19) United States
(12) Patent Application Publication
(10) Pub. No.: US 2026/0304592 A1
(43) Pub. Date: Oct. 1, 2026

(54) THERMAL COOLING SOLUTIONS FOR VARIABLE HEIGHT DEVICES IN AN OPTICAL MODEM CLAMSHELL ASSEMBLY

(71) Applicant: Ciena Corporation, Hanover, MD (US)

(72) Inventors: Yannick Brisebois, Ottawa (CA); Victor Aldea, Ottawa (CA); Bonnie Mack, Carp (CA)

(21) Appl. No.: 19/095,204

(22) Filed: Mar. 31, 2025

(51) Int. Cl. H05K 1/02

(52) U.S. Cl. CPC H05K 1/0203; H05K 2201/064; H05K 2201/10598

(57) ABSTRACT

An optical modem clamshell assembly including a printed circuit board assembly including at least one component, a top plate, a first floating heatsink disposed between and in thermal communication with a first component and the top plate, where the first floating heatsink is biased away from the top plate to provide a first thermal contact pressure to the first component, and, optionally or alternatively, a second floating heatsink disposed between and in thermal communication with a second component and the top plate, where the second floating heatsink is biased away from the top plate to provide a second thermal contact pressure to the second component. The top plate may include an embedded heatsink, the first floating heatsink may be a vapor chamber, and the second floating heatsink may be a plate with a heat pipe thermally coupled between the floating plate and the top plate remote from the embedded heatsink.

### TECHNICAL FIELD

The present disclosure relates generally to the telecommunications and networking fields. More particularly, the present disclosure relates to thermal cooling solutions for variable height devices in an optical modem clamshell assembly.

### BACKGROUND

In current printed circuit board assembly (PCBA) optical modem clamshell assemblies, the standard thermal solution is to have a single top plate that encloses and presses down on all internal components that require cooling, including a bare-die component and optical components. Due to the tolerances of the internal components, the top plate usually leaves a large gap between the internal components and the top plate. The tolerances of the internal components are typically taken up by a relatively thick thermal interface material (TIM). This single top plate design means that the applied pressures for each internal component may be too little or too much, often resulting in overheating of an internal component on the PCBA (due to too little pressure applied to the internal component through the TIM) or breaking the internal component on the PCBA (due to too much pressure applied to the internal component through the TIM). Further, the single top plate design limits where the cooling of a given internal component takes place as conduction through the TIM to the top plate is directly over the internal component to be cooled.

Optical modem clamshell assemblies with multiple top plates associated with different internal components are difficult to mount additional heatsinks to because the surfaces of the top plates might not be even or may be too small for proper thermal cooling. Further, such multiple top plate designs may not protect the PCBA as well as the single top plate design as a whole.

The present background is provided as illustrative environmental context only and should not be construed to be limiting in any manner. It will be readily apparent to those of ordinary skill in the art that the principles and concepts of the present disclosure may be applied in other environmental contexts equally, without limitation. For example, the principles and concepts of the present disclosure may be applied to telecommunication and networking devices other than an optical modem.

### SUMMARY

The present disclosure provides a thermal cooling solution that applies precise heatsink pressure to the internal components of an optical modem PCBA clamshell assembly while still using a single top plate to cool the clamshell assembly. This top plate provides a better surface for the mounting of a large heatsink and enables cooling the internal components on the PCBA more effectively. The thermal cooling solution accommodates variable height devices in a fixed height clamshell assembly and enables the application of a specific force to each internal component. Issues related to uneven or uncontrolled pressure are eliminated, the proper pressure may be applied to each sensitive internal component, and heat transfer from the internal components to the top plate, bottom plate, and the clamshell housing is enhanced, preventing the internal components from overheating during operation. Heat from an internal component with a low temperature limit may be moved to a cooler section of the top plate, away from that internal component.

In the optical modem clamshell assembly of the present disclosure, the top plate includes an embedded heatsink, or embedded vapor chamber (VC), that is thermally coupled to a floating heatsink, or floating VC, through an intervening TIM. The floating VC is coupled to and biased away from the interior of the top plate via a plurality of fasteners and resilient members, such as screws and springs or the like, and into a first internal component, such as a bare-die component, coupled to the PCBA within the clamshell assembly. Another TIM is provided between the floating VC and the first internal component. Thus, a thermal path can be established between the first internal component and the embedded VC and top plate with a controlled pressure via the floating VC that provides a degree of tolerance within the fixed envelope of the clamshell assembly.

In the optical modem clamshell assembly of the present disclosure, the top plate also includes a floating plate that is coupled to and biased away from the interior of the top plate via a plurality of fasteners and resilient members, such as screws and springs or the like, and into at least a second internal component, such as an optical component, coupled to the PCBA adjacent to the first internal component within the clamshell assembly. A further TIM may be provided between the floating plate and the second internal component. Thus, a thermal path can be established between the second internal component and the top plate again with a controlled pressure via the floating plate that provides a degree of tolerance within the fixed envelope of the clamshell assembly. The floating plate is also thermally coupled to a heat pipe that serves to distribute heat to other portions of the top plate away from the floating plate and the second internal component. An air gap and/or thermal insulator are provided between the floating plate and the embedded VC in any areas of overlap to prevent heat bleeding from the first internal component and the embedded VC to the floating plate and the second internal component.

The result is that separate pressure-controlled thermal paths are provided from the first internal component and the second internal component to the single top plate of the clamshell assembly, isolating the thermal components from each other to a desired degree. The cooling surface of the top plate is enhanced via the embedded VC and the heat pipe used to spread heat across the top plate.

In some embodiments, the present disclosure provides an optical modem clamshell assembly including a printed circuit board assembly including at least one component, a top plate, optionally including an embedded heatsink, a first floating heatsink disposed between and in thermal communication with a first component and the top plate, where the first floating heatsink is biased away from the top plate, and optionally the embedded heatsink of the top plate, to provide a first thermal contact pressure to the first component. Optionally or alternatively, the optical modem clamshell assembly includes a second floating heatsink disposed between and in thermal communication with a second component and the top plate, where the second floating heatsink is biased away from the top plate to provide a second thermal contact pressure to the second component. The optical modem clamshell assembly further includes a heat pipe thermally coupled between the second floating heatsink and the top plate remote from the embedded heatsink. The optical modem clamshell assembly further includes a thermal interface material disposed between one or more of the first component and the first floating heatsink, the first floating heatsink and the embedded heatsink of the top plate, and the second component and the second floating heatsink. In some embodiments, the optical modem clamshell assembly further includes an insulating gap disposed between the second floating heatsink and an overlapped portion of the embedded heatsink of the top plate. In some embodiments, the optical modem clamshell assembly further includes a thermal insulator disposed within the insulating gap. In some embodiments, the first component is a bare-die component having a first height above a printed circuit board of the printed circuit board assembly and the second component is an optical component having a second height above the printed circuit board of the printed circuit board assembly. In some embodiments, the embedded heatsink is an embedded vapor chamber coupled to or incorporated into the top plate, the first floating heatsink is a floating vapor chamber, and the second floating heatsink is a floating plate. The optical modem clamshell assembly further includes a bottom plate, where the bottom plate and the top plate are coupled together to form a fixed height envelope in which the printed circuit board assembly is disposed.

In some embodiments, the present disclosure provides an optical modem device including a printed circuit board assembly including at least one component, a top plate, optionally including an embedded heatsink, a bottom plate, where the bottom plate and the top plate are coupled together to form a fixed height envelope in which the printed circuit board assembly is disposed, a first floating heatsink disposed between and in thermal communication with a first component and the top plate, where the first floating heatsink is biased away from the top plate, and optionally the embedded heatsink of the top plate, to provide a first thermal contact pressure to the first component. Optionally or alternatively, the optical modem device includes a second floating heatsink disposed between and in thermal communication with a second component and the top plate, where the second floating heatsink is biased away from the top plate to provide a second thermal contact pressure to the second component. The optical modem device further includes a heat pipe thermally coupled between the second floating heatsink and the top plate remote from the embedded heatsink. The optical modem device further includes a thermal interface material disposed between one or more of the first component and the first floating heatsink, the first floating heatsink and the embedded heatsink of the top plate, and the second component and the second floating heatsink. In some embodiments, the optical modem device further includes an insulating gap disposed between the second floating heatsink and an overlapped portion of the embedded heatsink of the top plate. In some embodiments, the optical modem device further includes a thermal insulator disposed within the insulating gap. In some embodiments, the first component is a bare-die component having a first height above a printed circuit board of the printed circuit board assembly and the second component is an optical component having a second height above the printed circuit board of the printed circuit board assembly. In some embodiments, the embedded heatsink is an embedded vapor chamber coupled to or incorporated into the top plate, the first floating heatsink is a floating vapor chamber, and the second floating heatsink is a floating plate.

In some embodiments, the present disclosure provides an optical modem thermal cooling method including providing a printed circuit board assembly including at least one component, providing a top plate, optionally including an embedded heatsink, disposing a first floating heatsink between and in thermal communication with a first component and the top plate, where the first floating heatsink is biased away from the top plate to provide a first thermal contact pressure to the first component, and, optionally or alternatively, disposing a second floating heatsink between and in thermal communication with a second component and the top plate, where the second floating heatsink is biased away from the top plate, and optionally the embedded heatsink of the top plate, to provide a second thermal contact pressure to the second component. In some embodiments, the embedded heatsink is an embedded vapor chamber coupled to or incorporated into the top plate, the first floating heatsink is a floating vapor chamber, and the second floating heatsink is a floating plate. The optical modem thermal cooling method further includes thermally coupling a heat pipe between the second floating heatsink and the top plate remote from the embedded heatsink. The optical modem thermal cooling method further includes disposing a thermal interface material between one or more of the first component and the first floating heatsink, the first floating heatsink and the embedded heatsink of the top plate, and the second component and the second floating heatsink. In some embodiments, the optical modem thermal cooling method further includes disposing an insulating gap between the second floating heatsink and an overlapped portion of the embedded heatsink of the top plate. In some embodiments, the optical modem thermal cooling method further includes disposing a thermal insulator within the insulating gap.

It will be readily apparent to those of ordinary skill in the art that aspects and features of the described embodiments may be included, omitted, or combined as desired in a given application, without limitation.

### BRIEF DESCRIPTION OF THE DRAWINGS

The present disclosure is illustrated and described with reference to the various drawings, in which like reference numbers are used to denote like assembly components/method steps, as appropriate.

FIG. 1 is a perspective view of a PCBA of an optical modem clamshell assembly of the present disclosure, including a bare-die component and a plurality of optical components.

FIG. 2 is a perspective view of the optical modem clamshell assembly of the present disclosure, including the PCBA of FIG. 1, a bottom plate, and a top plate forming a fixed envelope housing.

FIG. 3 is an exploded perspective view of the optical modem clamshell assembly of FIG. 2, including the PCBA of FIG. 1, the bottom plate, and the top plate forming the fixed envelope housing.

FIG. 4 is a perspective (interior) view of the top plate of the optical model clamshell assembly of FIG. 2, including the embedded VC, the floating VC, the floating plate, and the heat pipe of the present disclosure.

FIG. 5 is a partially-exploded perspective (interior) view of the top plate of the optical model clamshell assembly of FIG. 2, including the embedded VC, the floating VC, the floating plate, and the heat pipe of the present disclosure.

FIG. 6 is another partially-exploded perspective (interior) view of the top plate of the optical model clamshell assembly of FIG. 2, including the embedded VC, the floating VC, the floating plate, and the heat pipe of the present disclosure.

FIG. 7 is a partial planar side view of the top plate of the optical model clamshell assembly of FIG. 2, including the embedded VC, the floating plate, and the heat pipe of the present disclosure.

FIG. 8 is another partial planar side view of the top plate of the optical model clamshell assembly of FIG. 2, including the embedded VC, the floating plate, and the heat pipe of the present disclosure.

FIG. 9 is a flowchart of the optical modem thermal cooling method of the present disclosure.

It will be readily apparent to those of ordinary skill in the art that aspects and features of the illustrated embodiments may be included, omitted, or combined as desired in a given application, without limitation.

### DETAILED DESCRIPTION

Again, the present disclosure provides a thermal cooling solution that applies precise heatsink pressure to the internal components of an optical modem PCBA clamshell assembly while still using a single top plate to cool the clamshell assembly. This top plate provides a better surface for the mounting of a large heatsink and enables cooling the internal components on the PCBA more effectively. The thermal cooling solution accommodates variable height devices in a fixed height clamshell assembly and enables the application of a specific force to each internal component. Issues related to uneven or uncontrolled pressure are eliminated, the proper pressure may be applied to each sensitive internal component, and heat transfer from the internal components to the top plate, bottom plate, and the clamshell housing is enhanced, preventing the internal components from overheating during operation. Heat from an internal component with a low temperature limit may be moved to a cooler section of the top plate, away from that internal component.

In the optical modem clamshell assembly of the present disclosure, the top plate includes an embedded heatsink, or embedded VC, that is thermally coupled to a floating heatsink, or floating VC, through an intervening TIM. The floating VC is coupled to and biased away from the interior of the top plate via a plurality of fasteners and resilient members, such as screws and springs or the like, and into a first internal component, such as a bare-die component, coupled to the PCBA within the clamshell assembly. Another TIM is provided between the floating VC and the first internal component. Thus, a thermal path can be established between the first internal component and the embedded VC and top plate with a controlled pressure via the floating VC that provides a degree of tolerance within the fixed envelope of the clamshell assembly.

In the optical modem clamshell assembly of the present disclosure, the top plate also includes a floating plate that is coupled to and biased away from the interior of the top plate via a plurality of fasteners and resilient members, such as screws and springs or the like, and into at least a second internal component, such as an optical component, coupled to the PCBA adjacent to the first internal component within the clamshell assembly. A further TIM may be provided between the floating plate and the second internal component. Thus, a thermal path can be established between the second internal component and the top plate again with a controlled pressure via the floating plate that provides a degree of tolerance within the fixed envelope of the clamshell assembly. The floating plate is also thermally coupled to a heat pipe that serves to distribute heat to other portions of the top plate away from the floating plate and the second internal component. An air gap and/or thermal insulator are provided between the floating plate and the embedded VC in any areas of overlap to prevent heat bleeding from the first internal component and the embedded VC to the floating plate and the second internal component.

The result is that separate pressure-controlled thermal paths are provided from the first internal component and the second internal component to the single top plate of the clamshell assembly, isolating the thermal components from each other to a desired degree. The cooling surface of the top plate is enhanced via the embedded VC and the heat pipe used to spread heat across the top plate.

Thus, the present disclosure provides an assembly and method to thermally cool bare-die components and optical components with variable height tolerances and a range of temperature limits on an optical modem PCBA in a clamshell assembly. The assembly is designed to take up mechanical tolerances between these components and thermally couple the components to a top and bottom plate of the clamshell assembly such that a fixed overall thickness of the clamshell assembly is maintained and allows for the mounting of an external heatsink.

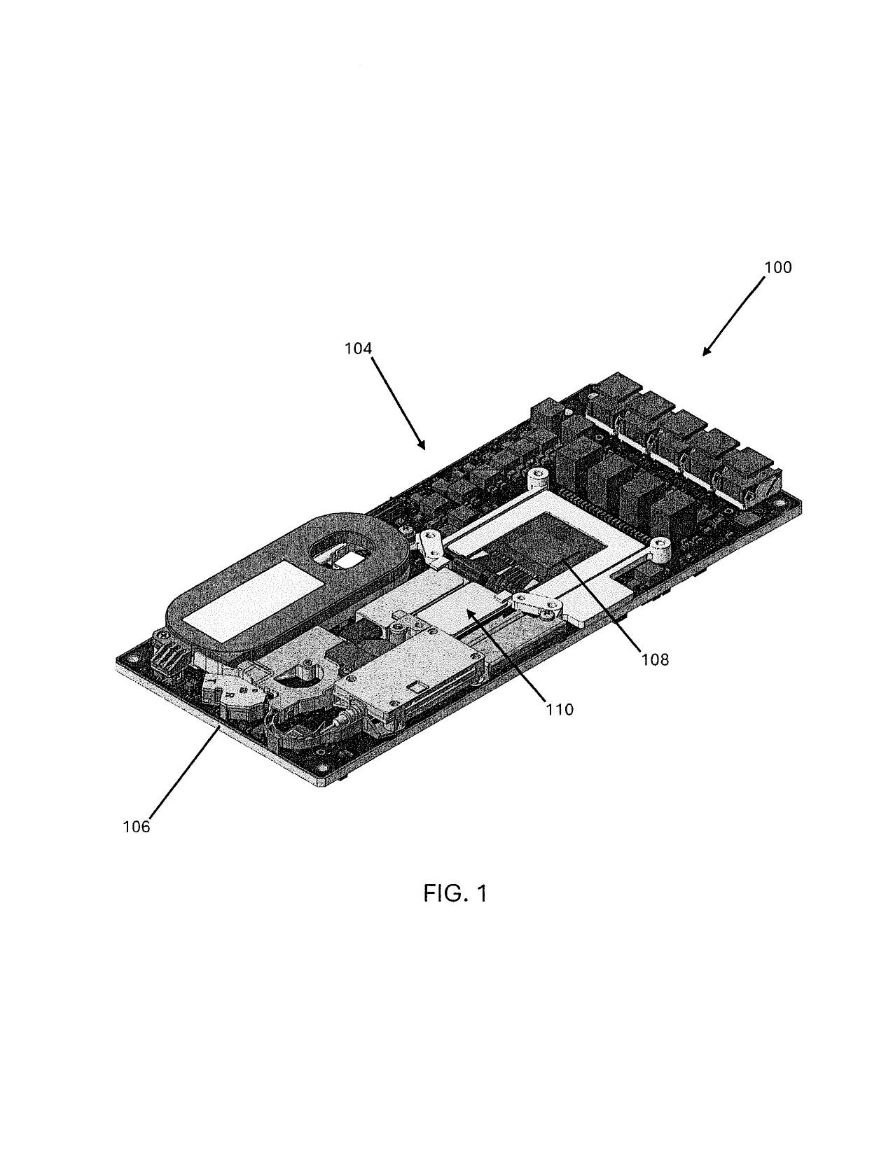

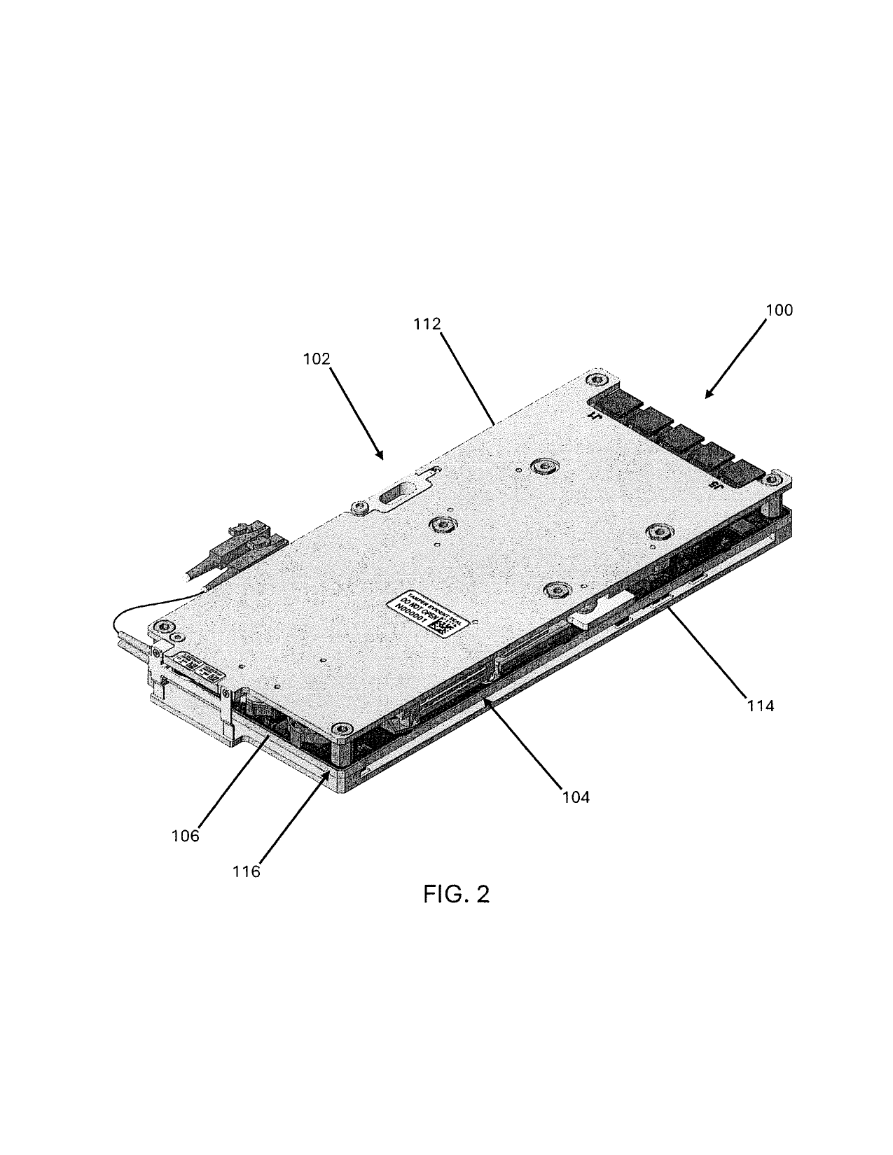

Referring to FIG. 1, the optical modem device 100 and optical modem clamshell assembly 102 (FIG. 2) of the present disclosure include a PCBA 104 which includes a printed circuit board (PCB) 106 on which a plurality of components are disposed, including a first bare-die component 108 and at least one second optical component 110, among other components. The first bare-die component 108 may be spaced apart from a top plate 112 (FIG. 2) of the clamshell assembly 102 by a first distance, providing a first mechanical tolerance, while the second optical component 110 may be spaced apart from the top plate 112 by a second distance, providing a second mechanical tolerance. The first mechanical tolerance may be greater than the second mechanical tolerance, for example, which must be accounted for in thermally coupling the first bare-die component 108 and the second optical component 110 to the single top plate 112 for heat spreading and thermal heatsink cooling of the components 108, 110 by the top plate 112. Further, the first bare-die component 108 and the second optical component 110 may have different heat tolerances, with the first bare die-component 108 running hotter than the second optical component 110, for example.

Referring to FIG. 2, the clamshell assembly 102 has a fixed envelope height when the top plate 112 is joined to the bottom plate 114 via a plurality of fixed height securement mechanisms 116, such as posts, bolts/sleeves, and screws, disposed through and/or abutting the PCB 106 of the PCBA 104. Due to this fixed envelope height, the thermal coupling mechanism(s) between the first bare-die component 108 and the second optical component 110 and the top plate 112 must be able to span variable internal height gaps or tolerances. It will be readily apparent to those of ordinary skill in the art that, as used here, “top,” “bottom,” and other directional indicators are used in a relative sense only and should not be construed to require any absolute directional alignment. Similarly, terms like “first” and “second” are used merely to distinguish components and not to limit components or exclude the inclusion of additional components.

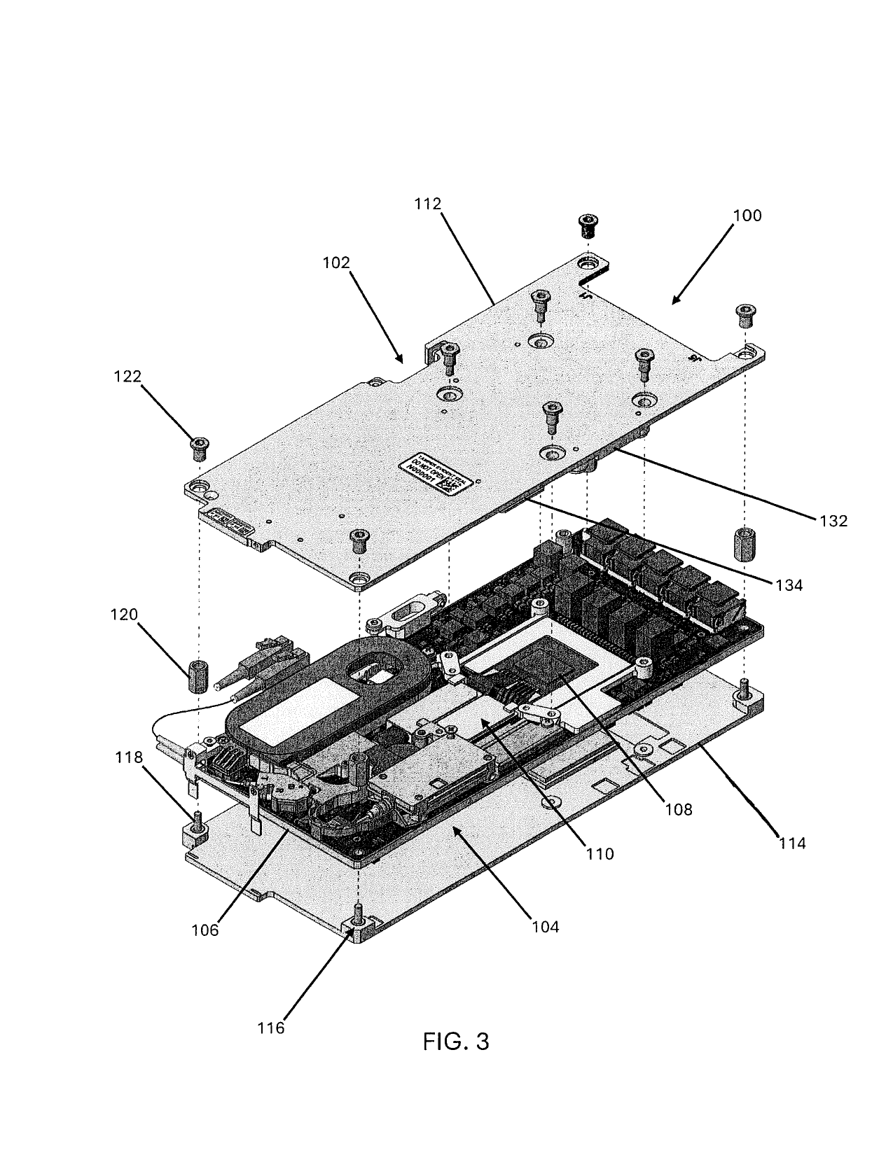

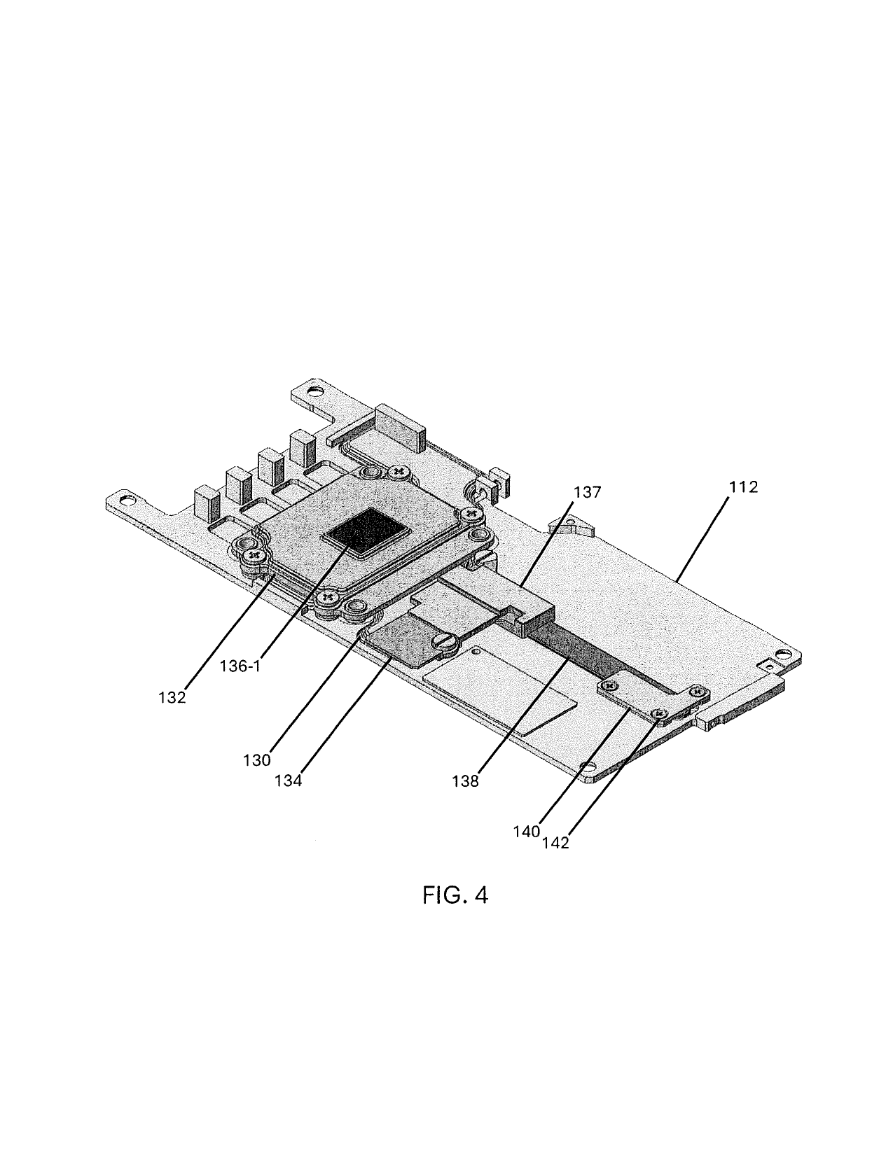

FIG. 3 shows the layered arrangement of the clamshell assembly 102, which forms the fixed height envelope of the optical modem device 100. Again, the top plate 112 is joined to the bottom plate 114 via the plurality of fixed height securement mechanisms 116, such as posts 118, bolts/sleeves 120, and screws 122, disposed through and/or abutting the PCB 106 of the PCBA 104. The space between the PCBA 104 and the top plate 112 defines the internal space or vertical tolerance that must be spanned or filled to provide a thermal transfer path between the first bare-die component 108 and the second optical component 110 and the top plate 112 such that the top plate 112 can be used as a heatsink. As is described in greater detail below, the top plate 112 may utilize an embedded VC 130 (FIG. 4) to cool the first bare-die component 108, a floating VC 132 is arranged between the first bare-die component 108 and the embedded VC 130 of the top plate 112 within the fixed envelope of the clamshell assembly 102 to thermally couple the first bare-die component 108 to the embedded VC 130, and a floating plate 134 is arranged between the second optical component 110 and the top plate 112 within the fixed envelope of the clamshell assembly 102 to thermally couple the second optical component 110 to the top plate 112. The floating VC 132 and the floating plate 134 flexibly accommodate the height variability of the first bare-die component 108 and the second optical component 110 with respect to the PCB 106. A TIM 136-1, 136-2, 137 (FIGS. 4-6) may be disposed in any/all thermal coupling interfaces. It should be noted that the floating VC 132 and the floating plate 134 are also generically referred to as the first floating heatsink 132 and the second floating heatsink 134, including if other than a VC and a plate are utilized, and are used to cool the generic first component 108 and second component 110, respectively. The present disclosure contemplates the cooling of at least one component on the PCB 106 using the first floating heatsink 132 and/or the cooling of at least one other component on the PCB 106 using the second floating heatsink 134. Thus, the first floating heatsink 132 and the second floating heatsink 134 may be used independently or in combination, depending on the arrangement of components on the PCB 106 to be cooled.

Again, in the embodiment illustrated, the PCBA 104 of the optical modem device 100 has internal components 108, 110 that require thermal cooling. Some such internal components are high-power bare-die components 108 that require a specific pressure range to cool properly. Other internal components are very temperature sensitive optical components 110. These internal components 108, 110 can have large variable height tolerances and require a constant pressure to be applied to minimize the required TIM thickness to sufficiently cool the PCBA 104. These internal components 108, 100 may also have different operating temperature limits. A typical optical modem clamshell assembly 102 utilizes the PCBA 104 sandwiched between the bottom plate 114 and the top plate 112. The top plate 112 and the bottom plate 114 serve to protect the PCBA 104 and as heatsinks to thermally cool the temperature sensitive internal components 108, 100.

Referring to FIG. 4, the interior surface of the top plate 112 includes the optional embedded VC 130 and the floating VC 132 disposed in an area adapted to be thermally coupled to the first bare-die component 108 when the top plate is coupled to the PCBA 104 and the bottom plate 114, and the floating plate 134 disposed in an area adapted to be thermally coupled to the second optical component 110 when the top plate is coupled to the PCBA 104 and the bottom plate 114. The floating VC 132 is biased away from the top plate 112 and the optional embedded VC 130 such that the floating VC 132 applies a predetermined pressure to the first bare-die component 108, optionally through an intervening TIM 136-1. Advantageously, the thickness of the TIM 136-1 may be minimized due to the presence of the floating VC 132 in the thermal space between the first bare-die component 108 and the top plate 112. The floating plate 134 is also (separately) biased away from the top plate 112 such that the floating plate 134 applies a (separate) predetermined pressure to the second optical component 110, optionally through an intervening TIM 137. Again, the thickness of the TIM 137 may be minimized due to the presence of the floating plate 134 in the thermal space between the second optical component 110 and the top plate 112. Further, a heat pipe 138 is thermally coupled between the floating plate 134 and a remote location on the interior surface of the top plate 112 and serves to thermally communicate heat away from the floating plate 134 and spread the heat across the top plate 112. VCs and their use in heatsink applications are well known to those of ordinary skill in the art, as are heat pipes and their use in heatsink applications. It should be noted that the heat pipe 138 may be manufactured from a rigid or semi-rigid material that also serves to bias the floating plate 114 away from the top plate 112. The remote end of the heat pipe 138 is secured to the interior surface of the top plate by a retaining plate 140 and a plurality of retaining screws 142, for example. The heat pipe 138 may be a solid or hollow and may have any cross-sectional shape desired in a given application.

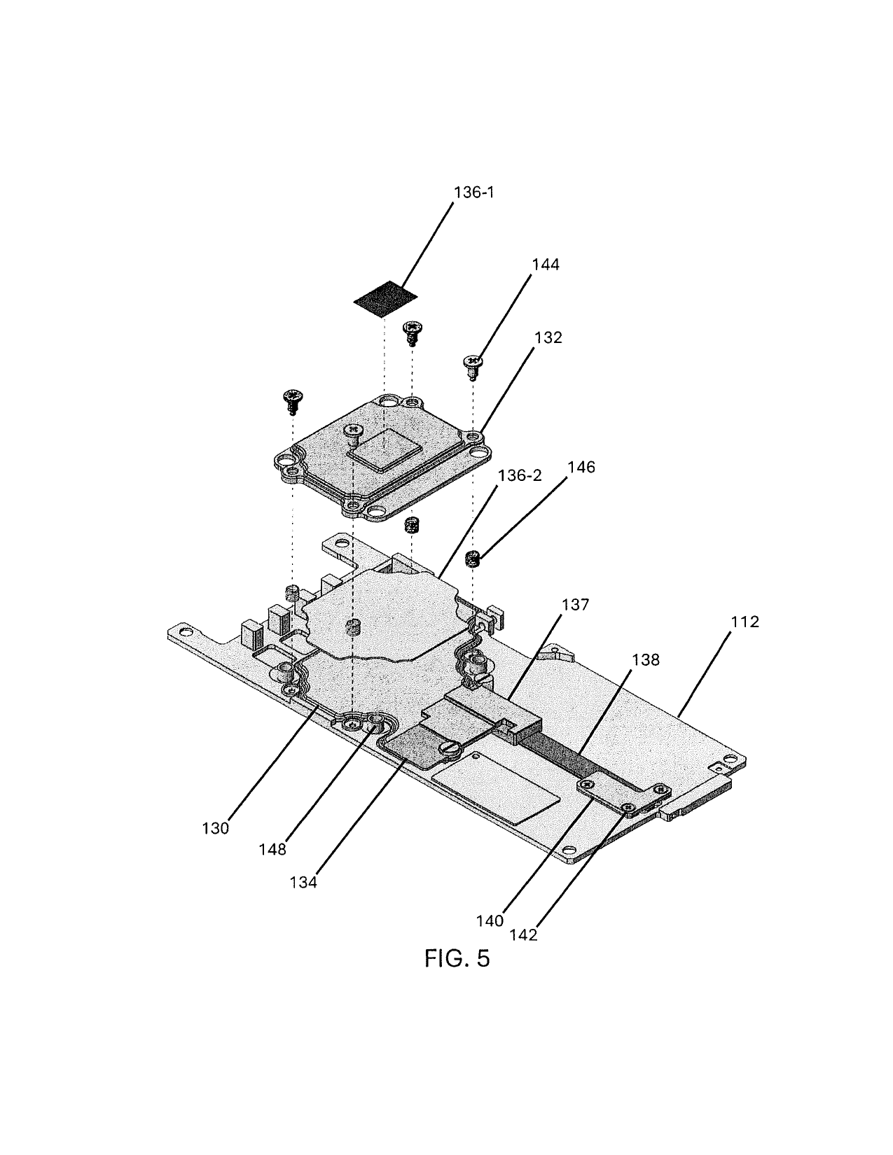

Referring to FIG. 5, the embedded VC 130, when used, may be manufactured into or coupled to the interior surface of the top plate 112. The floating VC 132 is biased away from the top plate 112 such that the floating VC 132 applies the predetermined pressure to the first bare-die component 108, through the intervening TIM 136-1, via a plurality of screws 144 along which the floating VC 132 is allowed to translate, with springs 146 disposed around the screws 144 between the floating VC 132 and the top plate 112. These springs 146 serve to provide the predetermined thermal contact pressure between the floating VC 132 and the first bare-die component 108 when the clamshell assembly 102 is assembled. A TIM 136-2 is also provided between the floating VC 132 and the top plate 112, providing a thermal interface when the floating VC 132 is pressed into thermal contact with the top plate 112. Again, the thickness of the TIMs 136-1, 136-2 may be minimized due to the presence of the floating VC 132 in the thermal space between the first bare-die component 108 and the top plate 112.

Thus, the first design of the present disclosure uses the floating VC 132 that is spring-mounted to the top plate 112 via the shoulder screws 144 and springs 146. The top plate 112 has pins 148 to align the floating VC 132 and keep the floating VC 132 parallel to the first bare-die component 108. The top plate 112 has the embedded VC 130 to spread heat across the top plate 112. The TIM 137 is provided between the floating VC 132 and the embedded VC 130. When the top plate 112 is mounted to the PCBA 104, the springs 146 holding the floating VC 132 provide pressure against the first bare-die component 108. The controlled length of the shoulder screws 144 and the stiffness of the springs 146 provide the precise amount of pressure applied to the first bare-die component 108 based on the tolerance of the height of the first bare-die component 108. The length of the shoulder screws 144 and spring force of the springs 146 are calculated based on the associated dimensions and assembly tolerances.

It should be noted that the floating VC 132 and the floating plate 134 are different components. The floating VC 132 is used to cool the first bare-die component(s) 108 with both high power and high heat flux. VCs are well known technology to those of ordinary skill in the art and use a closed evaporating and condensing cycle to provide an effective thermal conductivity path that is at least an order of magnitude higher than that of copper or the like. VCs spread localized heat in two dimensions. The floating plate 134 is used to cool the second optical component(s) 110. The floating plate 134 mehcnically and thermally couples the heat pipe 138 to the second optical component(s) 110, and also acts as a heat spreader for these lower-power optical components. Due to this lower power, the thermal conductivity of copper or the like is sufficent as a heat spreader for the second optical component(s) 110. The heat pipe 138 uses the same or similar closed evaporating and condensing technology as a VC, but only moves heat in one direction, rather than spreading it in two dimensions.

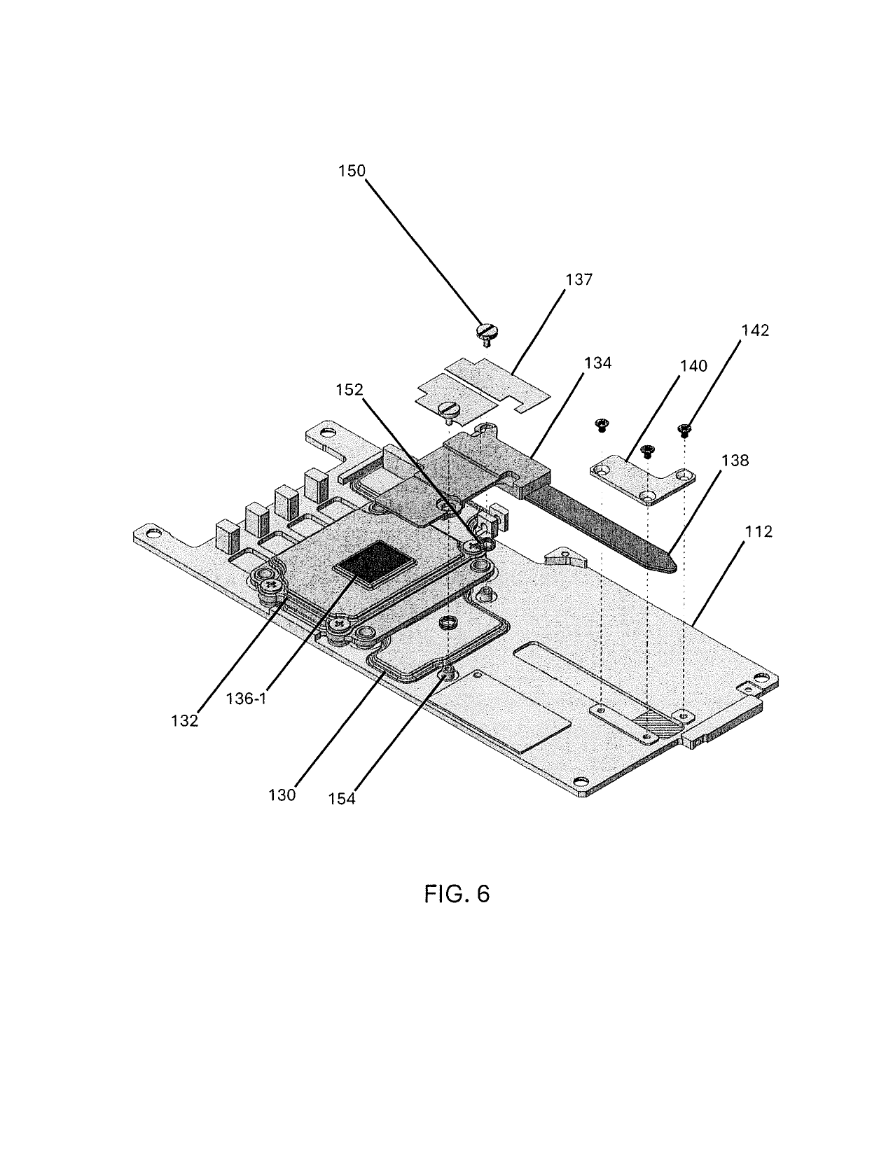

Referring to FIG. 6, the floating plate 134 is biased away from the top plate 112 such that the floating plate 134 applies the predetermined pressure to the second optical component 110, through the intervening TIM 137, via a plurality of screws 150 along which the floating plate 134 is allowed to translate, with springs 152 disposed around the screws 150 between the floating plate 134 and the top plate 112. These springs 152 serve to provide the predetermined thermal contact pressure between the floating plate 134 and the second optical component 110 when the clamshell assembly 102 is assembled. Again, the thickness of the TIM 137 (which may consist of multiple TIM pieces) may be minimized due to the presence of the floating plate 134 in the thermal space between the second optical component 110 and the top plate 112.

Thus, the second design of the present disclosure uses the floating plate 134 that is held in place by the screws 150, the springs, 152, and the heat pipe 138. One end of the heat pipe 138 is attached to the floating plate 134, while the other end of the heat pipe 138 is attached to a remote portion of the top plate 112 by brazing or the retaining plate 140. The springs 152 apply pressure to the second optical component 110 (and, optionally, multiple second optical components 110), causing a cantilever effect on the heat pipe 138. Heat is communicated from the second optical component 110 to a cooler area on the top plate 112, where the remote end of the heat pipe 138 is fixed. The top plate 112 has pins 154 to align the floating plate 134 and keep the floating plate 134 parallel to the second optical component 110. As described in greater detail below, to reduce heat bleeding from the bare-die internal component 108 to the optical internal components 110, a thermal insulator 162 may be disposed between the floating plate 134 and embedded VC 130. A small air gap 160 also helps with reducing the related heat transfer.

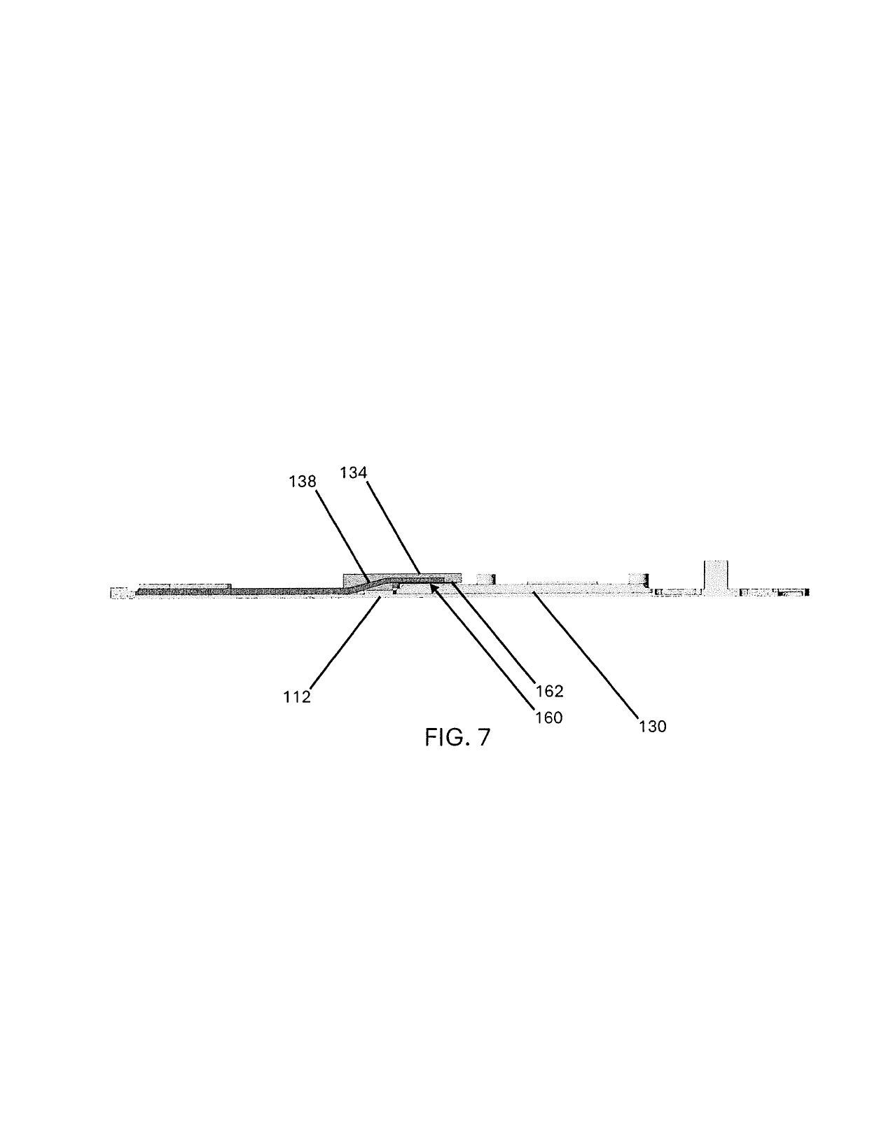

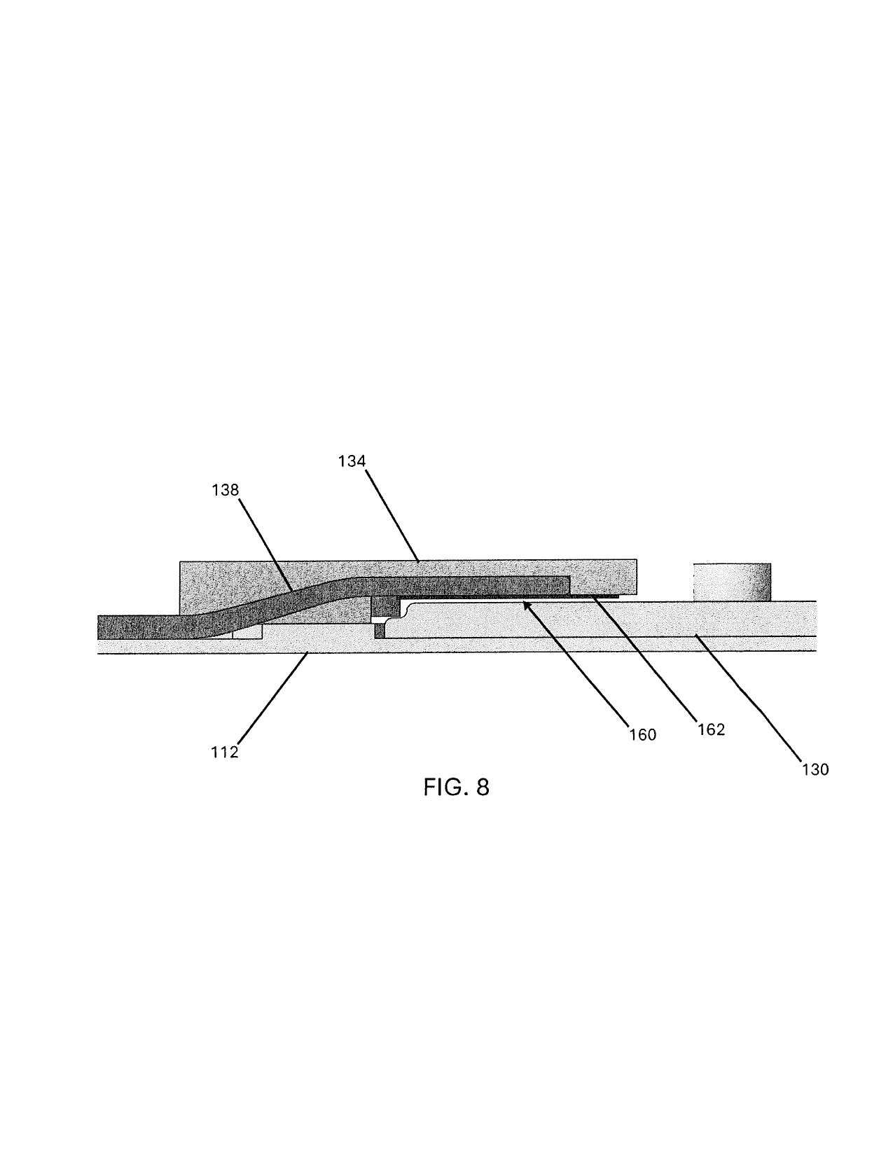

Referring to FIGS. 7 and 8, the small air gap 160 and/or the thermal insulator 162 are disposed between the floating plate 134 and embedded VC 130 where the floating plate 134 overlaps the embedded VC 130. This serves to reduce or prevent heat transfer between the embedded VC 130 and the floating plate 134, and between the first bare-die component 108 and the second optical component 110, the latter of which may be cooler and more sensitive to heat.

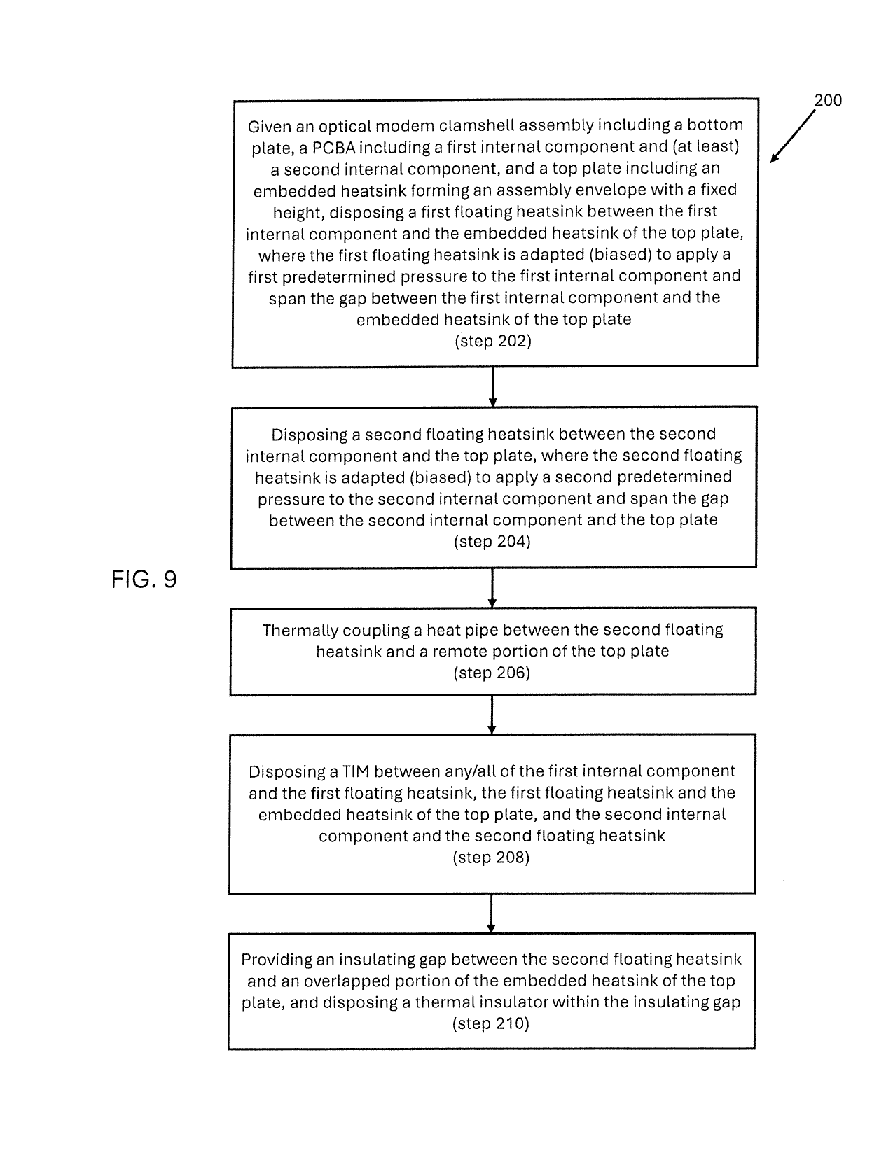

Referring to FIG. 9, the optical modem thermal cooling method 200 of the present disclosure includes, given an optical modem clamshell assembly including a bottom plate, a PCBA including a first internal component and (at least) a second internal component, and a top plate including an embedded heatsink forming an assembly envelope with a fixed height, disposing a first floating heatsink between the first internal component and the embedded heatsink of the top plate, where the first floating heatsink is adapted (biased) to apply a first predetermined pressure to the first internal component and span the gap between the first internal component and the embedded heatsink of the top plate (step 202). The method 200 also includes disposing a second floating heatsink between the second internal component and the top plate, where the second floating heatsink is adapted (biased) to apply a second predetermined pressure to the second internal component and span the gap between the second internal component and the top plate (step 204). The method 200 further includes thermally coupling a heat pipe between the second floating heatsink and a remote portion of the top plate (step 206). Optionally, the method 200 further includes disposing a TIM between any/all of the first internal component and the first floating heatsink, the first floating heatsink and the embedded heatsink of the top plate, and the second internal component and the second floating heatsink (step 208). Optionally, the method 200 further includes providing an insulating gap between the second floating heatsink and an overlapped portion of the embedded heatsink of the top plate, and disposing a thermal insulator within the insulating gap (step 210). As described above, the first internal component may be a bare-die component, the second internal component may be an optical component, the embedded heatsink may be an embedded VC, the first floating heatsink may be a floating VC, the second floating heatsink may be a floating plate and the top plate is a single, common top plate.

Thus, again, the present disclosure provides a thermal cooling solution that applies precise heatsink pressure to the internal components of an optical modem PCBA clamshell assembly while still using a single top plate to cool the clamshell assembly. This top plate provides a better surface for the mounting of a large heatsink and enables cooling the internal components on the PCBA more effectively. The thermal cooling solution accommodates variable height devices in a fixed height clamshell assembly and enables the application of a specific force to each internal component. Issues related to uneven or uncontrolled pressure are eliminated, the proper pressure may be applied to each sensitive internal component, and heat transfer from the internal components to the top plate, bottom plate, and the clamshell housing is enhanced, preventing the internal components from overheating during operation. Heat from an internal component with a low temperature limit may be moved to a cooler section of the top plate, away from that internal component.

The result is that separate pressure-controlled thermal paths are provided from the first internal component and the second internal component to the single top plate of the clamshell assembly, isolating the thermal components from each other to a desired degree. The cooling surface of the top plate is enhanced via the embedded VC and the heat pipe used to spread heat across the top plate.

Although the present disclosure is illustrated and described with reference to specific embodiments and examples, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. An optical modem clamshell assembly comprising
a printed circuit board assembly comprising at least one component,
a top plate, and
a floating heatsink disposed between and in thermal communication with the at least one component and the top plate, wherein the floating heatsink is biased away from the top plate to provide a thermal contact pressure to the at least one component.

2. The optical modem clamshell assembly of claim 1, wherein the floating heatsink includes one or more of
a first floating heatsink disposed between and in thermal communication with a first component of the at least one component and an embedded heatsink of the top plate, wherein the first floating heatsink is biased away from the embedded heatsink of the top plate to provide a first thermal contact pressure to the first component, and
a second floating heatsink disposed between and in thermal communication with a second component of the at least one component and the top plate, wherein the second floating heatsink is biased away from the top plate to provide a second thermal contact pressure to the second component.

3. The optical modem clamshell assembly of claim 2, further comprising
a heat pipe thermally coupled between the second floating heatsink and the top plate remote from the embedded heatsink.

4. The optical modem clamshell assembly of claim 2, further comprising a thermal interface material disposed between one or more of
the first component and the first floating heatsink,
the first floating heatsink and the embedded heatsink of the top plate, and
the second component and the second floating heatsink.

5. The optical modem clamshell assembly of claim 2, further comprising
an insulating gap disposed between the second floating heatsink and an overlapped portion of the embedded heatsink of the top plate.

6. The optical modem clamshell assembly of claim 5, further comprising
a thermal insulator disposed within the insulating gap.

7. The optical modem clamshell assembly of claim 2, wherein the first component is a bare-die component having a first height above a printed circuit board of the printed circuit board assembly and the second component is an optical component having a second height above the printed circuit board of the printed circuit board assembly.

8. The optical modem clamshell assembly of claim 2, wherein the embedded heatsink is an embedded vapor chamber coupled to or incorporated into the top plate, the first floating heatsink is a floating vapor chamber, and the second floating heatsink is a floating plate.

9. The optical modem clamshell assembly of claim 1, further comprising
a bottom plate,
wherein the bottom plate and the top plate are coupled together to form a fixed height envelope in which the printed circuit board assembly is disposed.

10. An optical modem device comprising
a printed circuit board assembly comprising at least one component,
a top plate,
a bottom plate, wherein the bottom plate and the top plate are coupled together to form a fixed height envelope in which the printed circuit board assembly is disposed, and
a floating heatsink disposed between and in thermal communication with the at least one component and the top plate, wherein the floating heatsink is biased away from the top plate to provide a thermal contact pressure to the at least one component.

11. The optical modem device of claim 10, wherein the floating heatsink includes one or more of
a first floating heatsink disposed between and in thermal communication with a first component of the at least one component and an embedded heatsink of the top plate, wherein the first floating heatsink is biased away from the embedded heatsink of the top plate to provide a first thermal contact pressure to the first component, and
a second floating heatsink disposed between and in thermal communication with a second component of the at least one component and the top plate, wherein the second floating heatsink is biased away from the top plate to provide a second thermal contact pressure to the second component.

12. The optical modem device of claim 11, further comprising
a heat pipe thermally coupled between the second floating heatsink and the top plate remote from the embedded heatsink.

13. The optical modem device of claim 11, further comprising a thermal interface material disposed between one or more of
the first component and the first floating heatsink,
the first floating heatsink and the embedded heatsink of the top plate, and
the second component and the second floating heatsink.

14. The optical modem device of claim 11, further comprising
an insulating gap disposed between the second floating heatsink and an overlapped portion of the embedded heatsink of the top plate.

15. The optical modem device of claim 14, further comprising
a thermal insulator disposed within the insulating gap.

16. The optical modem device of claim 11, wherein the first component is a bare-die component having a first height above a printed circuit board of the printed circuit board assembly and the second component is an optical component having a second height above the printed circuit board of the printed circuit board assembly.

17. The optical modem device of claim 11, wherein the embedded heatsink is an embedded vapor chamber coupled to or incorporated into the top plate, the first floating heatsink is a floating vapor chamber, and the second floating heatsink is a floating plate.

18. An optical modem thermal cooling method comprising
providing a printed circuit board assembly comprising at least one component,
providing a top plate, and
disposing a floating heatsink between and in thermal communication with the at least one component and the top plate, wherein the floating heatsink is biased away from the top plate to provide a thermal contact pressure to the at least one component.

19. The optical modem thermal cooling method of claim 18, wherein the disposing the floating heatsink includes one or more of
disposing a first floating heatsink between and in thermal communication with a first component of the at least one component and an embedded heatsink of the top plate, wherein the first floating heatsink is biased away from the embedded heatsink of the top plate to provide a first thermal contact pressure to the first component, and
disposing a second floating heatsink between and in thermal communication with a second component of the at least one component and the top plate, wherein the second floating heatsink is biased away from the top plate to provide a second thermal contact pressure to the second component.

20. The optical modem thermal cooling method of claim 19, wherein the embedded heatsink is an embedded vapor chamber coupled to or incorporated into the top plate, the first floating heatsink is a floating vapor chamber, and the second floating heatsink is a floating plate, and further comprising
thermally coupling a heat pipe between the second floating heatsink and the top plate remote from the embedded heatsink, and
disposing an insulating gap between the second floating heatsink and an overlapped portion of the embedded heatsink of the top plate.
